(19) United States
(12) Patent Application Publication
(10) Pub. No.: US 2004/0103353 A1
(43) Pub. Date: May 27, 2004

(54) Failure analysis method

(75) Inventors: Tohru Koyama, Tokyo (JP); Yukari Imai, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/620,380

(22) Filed: Jul. 17, 2003

(30) Foreign Application Priority Data
Oct. 22, 2002 (JP) 2002-306856

(51) Int. Cl. G01R 31/28

(52) U.S. Cl. 714/724

(57) ABSTRACT

A failure analysis device and a failure analysis method which enable easily a specification of a position of a failure point which is obtained from a back side upon a wiring pattern image which is obtained from a front side is provided.

Part of a light (51a) which is irradiated upon a front surface of an analyzed wafer (100) is reflected from a metal wiring, and is taken as a first wiring pattern image which is a reflect image of the analyzed wafer (100) by the CCD (11). An infrared light component of the light (51a) which passes a gap between the metal wiring is taken as a second wiring pattern image which is a transmission image of the analyzed wafer (100) by an infrared light detector (12). Besides, the infrared light detector (12) also takes a failure light emission image by a failure point.

### BACKGROUND OF THE INVENTION

1. Field of the Invention

The present invention relates to a failure analysis of a semiconductor integrated circuit, and more particularly, it relates to a technique to specify a position of a failure point.

2. Description of the Background Art

Conventionally, an emission analysis method is widely known as a semiconductor failure analysis method to detect a faulty point (a failure point) of a semiconductor integrated circuit. The emission analysis method is an analysis method to take an image of a failure point by means of detecting a weak light which is generated by a current leak at the failure point and specify a position of the corresponding failure point.

In the meantime, a metal wiring layer makes progress to have a multilayer structure attendant upon an integration of a semiconductor integrated circuit in recent years. By reason that the metal wiring does not transmit a light, it becomes difficult to observe a light emission at, for example, a metal wiring layer of a lower position or a semiconductor element which is under the metal wiring layer from a front side of a wafer on which a semiconductor chip is formed. Thereupon, focusing attention on a fact that silicon transmits an infrared light whose wave length is 1 μm or more, a method to detect a failure point by detecting the infrared light component which is included in the light which the failure point generates from a back side of a silicon substrate (a back side of a wafer) is suggested (a back side emission analysis method) (for example, a patent document 1).

[Patent Document 1] Japanese Patent Application Laid-Open No. 13-33526 (2001), (pages 4 and 5, FIGS. 1 to 3).

After detecting the failure point by a back side emission analysis method, a physical analysis is performed to investigate a cause of the failure, and this analysis is normally performed from a front side of a semiconductor device. Therefore, it is important to specify accurately a position of a light emission point upon a wiring pattern image which is taken from the front side of the device.

As for the conventional back side emission analysis, the position of the failure point is specified by means of superposing a light emission image of the failure point which is taken from a back side of a wafer and a wiring pattern image of the device which is taken from the same back side of the wafer. Thus, in case that the specification of the position of the failure point upon the wiring pattern image which is taken from the front side of the device is needed, the position of the failure point upon a layout diagram is once specified by collating the layout diagram of the wiring pattern with the wiring pattern image which is taken from the back side by means of a CAD tool and so on such as the patent document 1 described above, at first. And afterwards, the position of the failure point upon the wiring pattern image which is taken from the front side is specified by collating the wiring pattern image which is taken from the front side with the layout diagram.

In such a manner, when specifying the position of the failure point which is taken from the back side upon the wiring pattern image which is taken from the front side, an intricate operation is accompanied by reason of an intermediation of a matching operation with the layout diagram once.

### SUMMARY OF THE INVENTION

The present invention is to provide a failure analysis device and a failure analysis method which enable easily a specification of a position of a failure point which is obtained from a back side upon a wiring pattern image which is obtained from a front side.

According to a first aspect of the present invention, a failure analysis method includes the following steps (a) to (c). The step (a) is a step to irradiate a first light which includes a component whose wave length is 1 μm or more upon a semiconductor chip which is an object for an analysis from a front side. The step (b) is a step to take a first wiring pattern image which is a reflected image of the semiconductor chip by the first light and a second wiring pattern image which is a transmission image of the semiconductor chip by the first light. The step (c) is a step to take a light emission image of the semiconductor chip by a failure point from a back side of the semiconductor chip. Moreover, both of the second wiring pattern image and the light emission image are taken by an identical image pickup device.

The light emission image by the failure point and the second wiring pattern image are both taken by the identical image pickup device, thus each analysis region (view) coincides with the other, and therefore, an alignment with each other can be easily performed. Besides, the first wiring pattern image is the reflected image from the front side, therefore, at least the wiring pattern image of a top layer of a multilayer wiring which is formed in the semiconductor chip can be obtained from the first wiring pattern image. Besides, the second wiring pattern image is the transmission image, thus the wiring pattern image of the top layer of the multilayer wiring is included in it, also. Therefore, an alignment of the first wiring pattern image with the second wiring pattern image can also be easily performed. Accordingly, an alignment of the first wiring pattern image which is taken from the front side of the semiconductor chip with a failure light emission image can be easily performed. That is, the specification of the position of the failure point which is taken from the back side upon the wiring pattern image which is obtained from the front side can be easily performed.

According to a second aspect of the present invention, a failure analysis method includes the following steps (a) and (b). The step (a) is a step to irradiate a laser beam scanning which includes a component whose wave length is 1 μm or more upon a semiconductor chip which is an object for an analysis, and take a first wiring pattern image which is a transmission image of the semiconductor chip by the laser beam and a second wiring pattern image which is a reflected image of the semiconductor chip by the laser beam. The step (b) is a step to take an image of a failure point of the semiconductor chip. Moreover, the step (a) is performed by a first image pickup device which is placed on a front side of the semiconductor chip and a second image pickup device which is placed on a back side of the semiconductor chip. Besides, the step (b) is performed by a third image pickup device which is placed on a back side of the semiconductor chip. Furthermore, in advance of the steps (a) and (b), an alignment of the second image pickup device with the third image pickup device is performed.

The first wiring pattern image and the second wiring pattern image are both laser scanning images which are based on an identical scanning of the laser beam, thus each analysis region coincides completely with the other, and therefore, an alignment can be easily performed. Besides, an alignment of the second wiring pattern image with the image of the failure point can also be easily performed by aligning the second image pickup device with the third image pickup device in advance. Accordingly, an alignment of the first wiring pattern image which is taken from the front side of the semiconductor chip with a failure light emission image can be easily performed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a drawing illustrating a formation of a failure analysis device according to a first preferred embodiment.

FIG. 2 is a drawing for describing an action of the failure analysis device according to the first preferred embodiment.

FIG. 3 is a drawing illustrating a formation of a failure analysis device according to a second preferred embodiment.

FIG. 4 is a drawing for describing an action of the failure analysis device according to the second preferred embodiment.

FIG. 5 is a drawing illustrating a formation of a failure analysis device according to a third preferred embodiment.

FIG. 6 is a drawing illustrating a formation of a failure analysis device according to a fourth preferred embodiment.

FIGS. 7 and 8 are drawings both illustrating a formation of a failure analysis device according to a fifth preferred embodiment.

### DESCRIPTION OF THE PREFERRED EMBODIMENTS

### First Preferred Embodiment

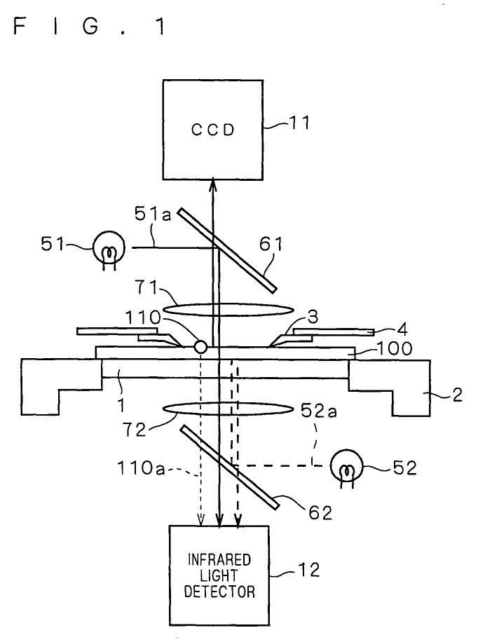

FIG. 1 is a drawing illustrating a formation of a failure analysis device according to a first preferred embodiment of the present invention. As shown in FIG. 1, a wafer chuck 1 to fix an analyzed wafer 100 in which a semiconductor chip which is an object for an analysis is formed is placed upon a wafer stage 2 which is movable in a horizontal direction. The wafer chuck 1 is generally formed of a quartz glass. A probe 3 which inputs/outputs a voltage signal to the chip of the analyzed wafer 100 is fixed to a probe card 4.

A first light source 51 and a second light source 52 emit a light which includes an infrared light component whose wave length is 1 μm or more, that is, for example, a halogen lamp. A light 51a which the first light source 51 radiates is reflected from a half mirror 61, and is irradiated on the analyzed wafer 100 from a front side through a lens optical system 71 to enlarge/ reduce an analysis region (view).

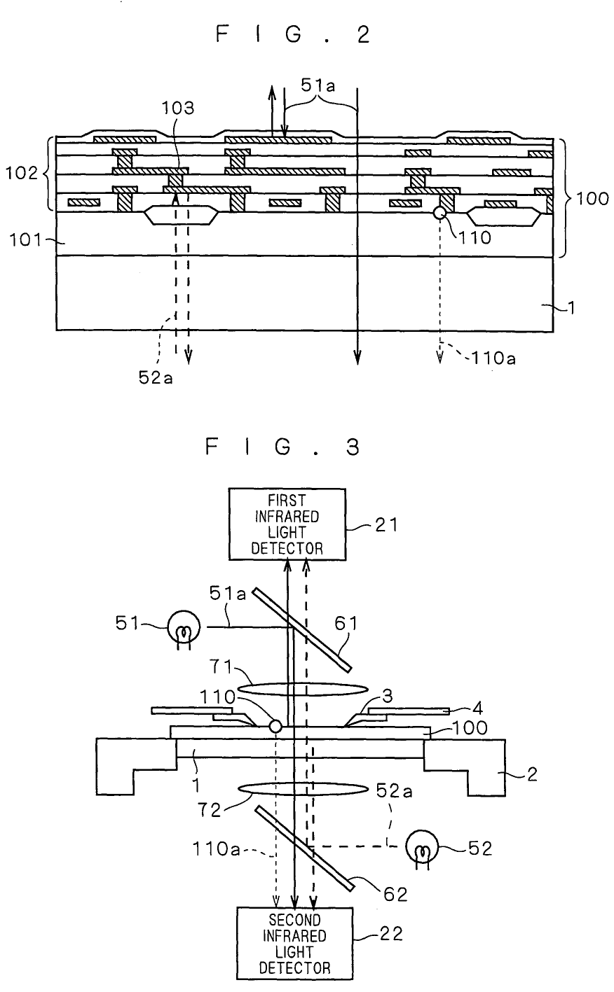

FIG. 2 is a drawing for describing an action of the failure analysis device according to the present preferred embodiment, and an enlarged cross sectional view of an analysis region of the analyzed wafer 100 and the wafer chuck 1. Here, as shown in FIG. 2, the analyzed wafer 100 is assumed to have a multilayer wiring structure. Part of the light 51a which is irradiated upon a front surface of the analyzed wafer 100 is reflected from a metal wiring 103 which is formed in a device forming layer 102 of the analyzed wafer 100. Moreover, it goes into a CCD 11 through the lens optical system 71 and the half mirror 61, and is taken as a first wiring pattern image which is a reflect image of the analyzed wafer 100 by the CCD 11. That is, the first wiring pattern image is a wiring pattern image which is taken from the front side of the analyzed wafer 100.

Besides, the infrared light component of the light 51a which passes a gap between the metal wiring 103 without being reflected from the metal wiring 103 transmits a silicon substrate 101, goes into an infrared light detector 12 through the wafer chuck 1, a lens optical system 72 and a half mirror 62 and is taken as a second wiring pattern image which is a transmission image of the analyzed wafer 100 by the infrared light detector 12. That is, the second wiring pattern image is a wiring pattern image which is taken from a back side of the analyzed wafer 100.

In the meantime, a light 52a which the second light source 52 emits is reflected from the half mirror 62 and is irradiated on the analyzed wafer 100 from a back side through the lens optical system 72 and the wafer chuck 1. The lens optical system 72 enlarges/ reduces an analysis region (view) and moreover, has a filter which passes only an infrared light component of the light 52a.

The infrared light component of the light 52a which is irradiated on the back surface of the analyzed wafer 100 reaches the device forming layer 102 transmitting the silicon substrate 101 of the analyzed wafer 100. Part of it is reflected from the metal wiring 103 which is formed in the device forming layer 102. Moreover, part of it goes into the infrared light detector 12 through the silicon substrate 101, the wafer chuck 1, the lens optical system 72 and the half mirror 62 and is taken as a third wiring pattern image which is a reflected image of the analyzed wafer 100 by the infrared light detector 12. That is, the third wiring pattern image is a wiring pattern image which is taken from the back side of the analyzed wafer 100.

Besides, the infrared light detector 12 is also used for detecting a failure point of the analyzed wafer 100. When a certain voltage signal is impressed into a chip upon the analyzed wafer 100 by the probe 3, a failure point 110 emits a light by reason of a current leak. An infrared light component 110a of the light goes into the infrared light detector 12 through the silicon substrate 101, the wafer chuck 1, the lens optical system 72 and the half mirror 62 and is taken as an image of a failure point (described as “a failure light emission image” hereinafter) by the infrared light detector 12.

Besides, the light emission from the failure point is extremely weak, therefore, a detector of a high photo sensitivity is needed to be used as the infrared light detector 12. However, in case of taking a wiring pattern image using the light sources 51 and 52, a light of extremely strong as compared with the failure light emission image is gone into the infrared light detector 12, therefore, an adjustment is needed to hold down the photo sensitivity to be low.

As described above, the CCD 11 takes the first wiring pattern image which is the wiring pattern image taken from the front side of the analyzed wafer 100, and the infrared light detector 12 takes the second wiring pattern image, the third wiring pattern image and the failure light emission image which are all taken from the back side of the analyzed wafer 100.

The failure light emission image, the second wiring pattern image and the third wiring pattern image are all taken by the identical infrared light detector 12, thus each analysis region (view) coincides with the other, and therefore, an alignment with each other can be easily performed. Besides, the first wiring pattern image is the reflected image from the front side, therefore, at least the wiring pattern image of a top layer of a multilayer wiring can be obtained from the first wiring pattern image. Besides, the second wiring pattern image is the transmission image, thus the wiring pattern image of the top layer of the multilayer wiring is included in it, also. Therefore, on the basis of the wiring pattern image of the top layer, an alignment of the first wiring pattern image with the second wiring pattern image can also be easily performed.

Accordingly, an alignment of the first wiring pattern image which is taken from the front side of the analyzed wafer 100 with the failure light emission image can be easily performed, according to the present preferred embodiment. That is, the specification of a position of the failure point which is taken from the back side upon the wiring pattern image which is obtained from the front side can be easily performed.

### Second Preferred Embodiment

In the first preferred embodiment, the CCD is used as a means of taking the wiring pattern image from the front side of the analyzed wafer 100, however, in the present embodiment, an infrared light detector is used instead. That is, as shown in FIG. 3, a failure analysis device according to the present preferred embodiment includes a first infrared light detector 21 and a second infrared light detector 22. Besides, in FIG. 3, identical codes are put on elements which are similar to FIG. 1, thus a detailed description is omitted here.

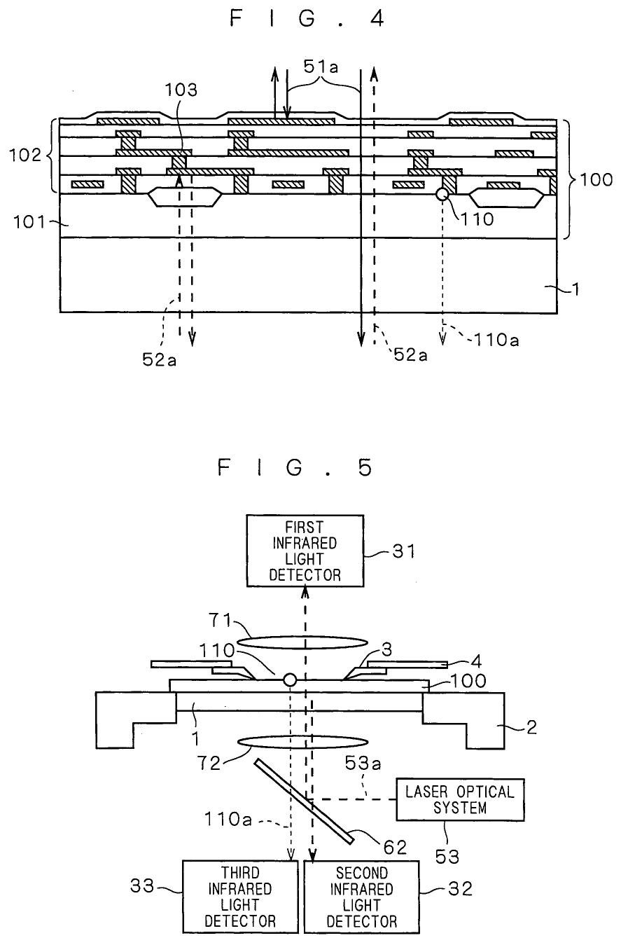

FIG. 4 is a drawing for describing an action of the failure analysis device according to the present preferred embodiment, and an enlarged cross sectional view of an analysis region of the analyzed wafer 100 and the wafer chuck 1. The light 51a which the first light source 51 emits is reflected from the half mirror 61 and is irradiated on the analyzed wafer 100 from the front side through the lens optical system 71. The lens optical system 71 has a filter which passes only the infrared light component of the light 51a.

Part of the infrared light component of the light 51a which is irradiated on the front surface of the analyzed wafer 100 is reflected from the metal wiring 103 which is formed in the device forming layer 102 of the analyzed wafer 100. Moreover, it goes into the first infrared light detector 21 through the lens optical system 71 and the half mirror 61 and is taken as the first wiring pattern image which is the reflected image of the analyzed wafer 100 by the first infrared light detector 21.

Besides, the infrared light component of the light 51a which passes the gap between the metal wiring 103 transmits the silicon substrate 101, goes into the second infrared light detector 22 through the wafer chuck 1, the lens optical system 72 and the half mirror 62 and is taken as the second wiring pattern image which is the transmission image of the analyzed wafer 100 by the second infrared light detector 22.

In the meantime, the light 52a which the second light source 52 emits is reflected from the half mirror 62 and is irradiated on the analyzed wafer 100 from a back side through the lens optical system 72 and the wafer chuck 1.

Part of the infrared light component of the light 52a which is irradiated on the back surface of the analyzed wafer 100 is reflected from the metal wiring 103 which is formed in the device forming layer 102. The infrared light component of the light 52a which is reflected from the metal wiring 103 goes into the second infrared light detector 22 through the silicon substrate 101, the wafer chuck 1, the lens optical system 72 and the half mirror 62 and is taken as the third wiring pattern image which is the reflected image of the analyzed wafer 100 by the second infrared light detector 22.

The infrared light component of the light 52a which passes the gap between the metal wiring 103 goes into the first infrared light detector 21 through the lens optical system 71 and the half mirror 61 and is taken as a fourth wiring pattern image which is a transmission image of the analyzed wafer 100 by the first infrared light detector 21.

Besides, in the same manner as the infrared light detector 12 in the first preferred embodiment, the second infrared light detector 22 takes the failure light emission image of the analyzed wafer 100 by the failure point.

As described above, the first infrared light detector 21 takes the first wiring pattern image which is the wiring pattern image taken from the front side of the analyzed wafer 100 and the fourth wiring pattern image, and the second infrared light detector 22 takes the second wiring pattern image which is the wiring pattern image taken from the back side of the analyzed wafer 100, the third wiring pattern image and the failure light emission image.

The failure light emission image, the second wiring pattern image and the third wiring pattern image are all taken by the identical infrared light detector 12, thus the alignment of them can be easily performed. Besides, the first wiring pattern image is the reflected image from the front side, therefore, at least the wiring pattern image of a top layer of a multilayer wiring can be obtained from the first wiring pattern image. The third wiring pattern image is the reflected image from the back side, therefore, at least the wiring pattern image of a bottom layer of a multilayer wiring can be obtained from the third wiring pattern image. In the meantime, the second wiring pattern image and the fourth wiring pattern image are the transmission images, thus the wiring pattern images of both the top layer and the bottom layer of the multilayer wiring is included in them, also. Therefore, on the basis of the wiring pattern image of the top layer or the bottom layer, they can be easy to be aligned with each other.

Accordingly, an alignment of the first wiring pattern image and the fourth wiring pattern image which are both taken from the front side of the analyzed wafer 100 with a failure light emission image can be easily performed, according to the present preferred embodiment. That is, the specification of the position of the failure point which is taken from the back side upon the wiring pattern image which is obtained from the front side can be easily performed. Besides, the two images, that is, the first wiring pattern image and the fourth wiring pattern image, can be obtained as the wiring pattern image which is obtained from the front side, therefore, by means of collating them with each other, more accurate specification of the position of the failure point as compared with the first preferred embodiment is also possible.

### Third Preferred Embodiment

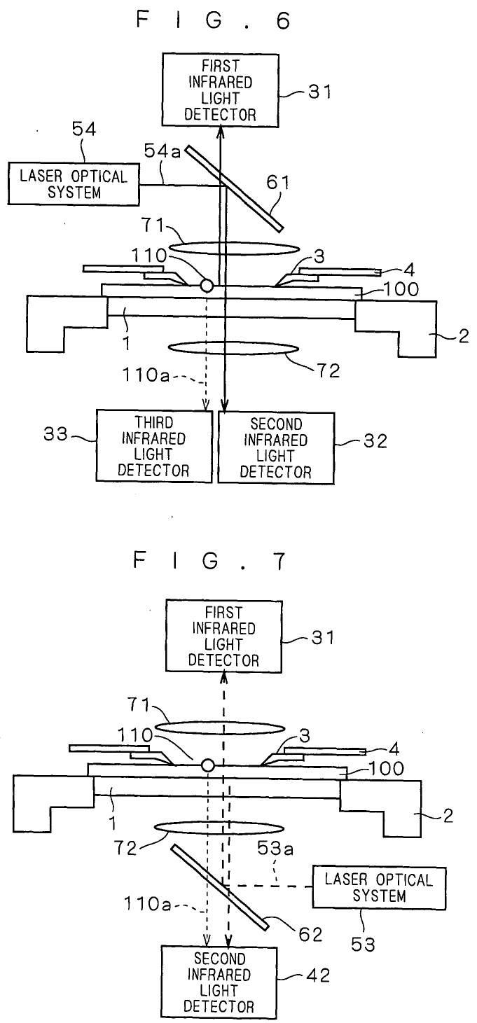

FIG. 5 is a drawing illustrating a formation of a failure analysis device according to a third preferred embodiment. In FIG. 5, identical codes are put on elements which are similar to FIG. 1, thus a detailed description is omitted here. In the present preferred embodiment, as a light source to obtain the wiring pattern image of the analyzed wafer 100, a laser optical system 53 which irradiates a laser beam 53 a scanning on the analyzed wafer 100 from the back side is used. The laser beam 53a which the laser optical system 53 emits includes the infrared light component whose wave length is 1 μm or more.

The laser beam 53a which is emitted from the laser optical system 53 reaches the analyzed wafer 100 through the half mirror 62, the lens optical system 72 and the wafer chuck 1. The infrared light component of the laser beam 53a which is reflected from the metal wiring 103 in the analyzed wafer 100 goes into a second infrared light detector 32. In the meantime, the infrared light component of the laser beam 53a which passes the gap between the metal wiring 103 goes into a first infrared light detector 31.

Each of the first infrared light detector 31 and the second infrared light detector 32 obtains a laser scanning image on the basis of a change in intensity of an incident light which synchronizes a scanning of the laser beam 53a. That is, the first infrared light detector 31 takes the first wiring pattern image which is a transmission image of the analyzed wafer 100 by the laser beam 53a as the laser scanning image. Besides, the second infrared light detector 32 takes the second wiring pattern image which is a reflected image of the analyzed wafer 100 by the laser beam 53a as the laser scanning image.

In the meantime, in the present preferred embodiment, the failure light emission image of the analyzed wafer 100 by the failure point is taken by a third infrared light detector 33. An action of the third infrared light detector 33 is similar to that of the infrared light detector 12 in the first preferred embodiment.

However, in the present preferred embodiment, a position adjustment is necessary that analysis regions (views) of the second infrared light detector 32 and the third infrared light detector 33 become identical with each other. Generally, by reason of a characteristic of the lens optical system 72, a distortion is slight in a center of the analysis region, thus an adjustment of a center of a region where the laser optical system 53 scans the laser beam 53a (that is, the center of the analysis region) with the center of the analysis region of the third infrared light detector 33 is recommendable for this position adjustment. For example, the position adjustment is possible by means of adjusting the position of the third infrared light detector 33 that a reflected light which comes from an irradiation on the center of a scanning region of the laser beam 53a goes into a center coordinates of the third infrared light detector 33. However, a light intensity of the laser beam 53a is extremely high, thus a sensitivity of the third infrared light detector 33 should be held down to be low.

As described above, the first infrared detector 31 takes the first wiring pattern image which is the wiring pattern image taken from the front side of the analyzed wafer 100, and the second infrared light detector 32 takes the second wiring pattern image which is the wiring pattern image taken from the back side of the analyzed wafer 100. Besides, the third infrared light detector 33 obtains the failure light emission image taken from the back side.

The first wiring pattern image and the second wiring pattern image are both the laser scanning images which are based on the identical scanning of the laser beam 53a, thus each analysis region coincides completely with the other, and therefore, an alignment can be easily performed. Besides, an alignment of the second infrared light detector 32 with the third infrared light detector 33 can be easily performed by reason of aligning the analysis region with each other in advance.

Accordingly, an alignment of the first wiring pattern image which is taken from the front side of the analyzed wafer 100 and the second wiring pattern image with the failure light emission image can be easily performed, according to the present preferred embodiment. That is, the specification of the position of the failure point which is taken from the back side upon the wiring pattern image which is obtained from the front side can be easily performed.

By the way, an OBIC method (an Optical Beam Induced Current method) and an OBIRCH method (an Optical Beam Induced Resistance Change method) are known as a method of detecting the failure point of the semiconductor device. The OBIC method is a method to take the image of the failure point by making display a current change at every scanning position as a brightness change while irradiating the laser beam scanning in the condition of impressing a low voltage on the semiconductor device which is the object for the analysis. The OBIRCH method is a method to take the image of the failure point by making display a resistance change corresponding with a temperature rise of the wiring as a brightness change by means of irradiating the laser beam scanning on the semiconductor device which is the object for the analysis.

The metal wiring does not transmit the laser beam, thus even in case of the OBIC method and the OBIRCH method, when the metal wiring layer has the multilayer structure, it is difficult to observe from the front side of the wafer. Accordingly, an Infrared OBIC method (IR—OBIC: Infrared OBIC) and an Infrared OBIRCH method (IR—OBIRCH: Infrared OBIRCH) that an infrared laser beam is irradiated from the back side of the wafer (side of a silicon substrate) are suggested.

For example, such as the failure analysis device according to the present preferred embodiment, if a device has a formation which has the laser optical system 53 which enables the irradiation of the laser beam 53a which includes the infrared light component scanning from the back side of the analyzed wafer 100, it is possible to perform the IR—OBIC method and the IR—OBIRCH method using it. That is, the image of the failure point can be taken using an IR—OBIC analysis device or an IR—OBIRCH analysis device as a third image pickup device instead of using the third infrared light detector 33. Besides, in this case, by coinciding the laser scanning region to perform the IR—OBIC method or the IR—OBIRCH method with the laser scanning region to take the first and the second wiring pattern images, the analysis region (view) can be coincided with each other. Hereby, the specification of the position of the failure point upon the first and the second wiring pattern images can be easily performed.

### Fourth Preferred Embodiment

FIG. 6 is a drawing illustrating a formation of a failure analysis device according to a fourth preferred embodiment. In FIG. 6, identical codes are put on elements which are similar to FIGS. 1 and 5. In the present preferred embodiment, as a light source to obtain the wiring pattern image of the analyzed wafer 100, a laser optical system 54 is used which irradiates a laser beam 54a scanning on the analyzed wafer 100 from the front side. The laser beam 54a which the laser optical system 54 emits includes the infrared light component whose wave length is 1 μm or more.

The laser beam 54a which is emitted from the laser optical system 54 is irradiated on the front surface of the analyzed wafer 100 through the half mirror 61 and the lens optical system 71. The infrared light component of the laser beam 54a which is reflected from the metal wiring 103 in the analyzed wafer 100 goes into the first infrared light detector 31. In the meantime, the infrared light component of the laser beam 54a which passes the gap between the metal wiring 103 goes into the second infrared light detector 32. That is, the first infrared light detector 31 takes the first wiring pattern image which is a reflected image of the analyzed wafer 100 by the laser beam 54a, and in the meantime, the second infrared light detector 32 takes the second wiring pattern image which is a transmission image of the analyzed wafer 100 by the laser beam 54a.

Besides, in the same manner as the third preferred embodiment, the third infrared light detector 33 takes the failure light emission image of the analyzed wafer 100 by the failure point. Besides, also in the present embodiment, the position adjustment is necessary that the analysis regions (views) of the second infrared light detector 32 and the third infrared light detector 33 become identical with each other in advance.

The first wiring pattern image and the second wiring pattern image are both the laser scanning images which are based on the identical scanning of the laser beam 54a, thus each analysis region coincides completely with the other, and therefore, the alignment can be easily performed. Besides, the alignment of the second infrared light detector 32 with the third infrared light detector 33 can be easily performed by reason of aligning the analysis region with each other in advance.

Accordingly, in the same manner as the third preferred embodiment, the alignment of the first wiring pattern image which is taken from the front side of the analyzed wafer 100 and the second wiring pattern image with the failure light emission image can be easily performed. That is, the specification of the position of the failure point which is taken from the back side upon the wiring pattern image which is obtained from the front side can be easily performed. Besides, the laser beam 54a is irradiated from the front side of the analyzed wafer 100, thus there is also an effect that the first wiring pattern image which is taken from the front side can be obtained more clearly.

### Fifth Preferred Embodiment

In the third and fourth preferred embodiments, a formation which includes the means of taking the failure light emission image (the third infrared light detector 33) separated from the means of obtaining the wiring pattern image taken from the back side of the analyzed wafer 100 is described. In the present preferred embodiment, the same two images are taken by one image pickup device.

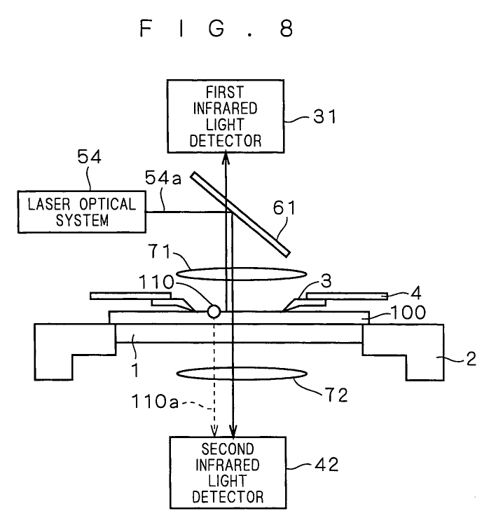

FIG. 7 is a drawing illustrating a formation of a failure analysis device according to the present preferred embodiment. In FIG. 7, identical codes are put on elements which are similar to FIGS. 1 and 5, thus a detailed description is omitted here.

The first infrared light detector 31 takes the first wiring pattern image which is the transmission image of the analyzed wafer 100 by the laser beam 53a. In the meantime, the second infrared light detector 42 takes both the second wiring pattern image which is the reflected image of the analyzed wafer 100 by the laser beam 53a and the failure light emission image by the failure point. However, the light intensity of the laser beam 53a is extremely strong as compared with the light emission from the failure point, therefore, in case of taking the second pattern image, an adjustment is needed to hold down the photo sensitivity of the second infrared light detector 42 to be low.

Besides, the first infrared light detector 31 obtains the first wiring image as the laser scanning image on the basis of the change in intensity of the incident light which synchronizes the scanning of the laser beam 53a. That is, an arithmetical operation is performed to convert the data obtained time-divisionally into the image. However, the second infrared light detector 42 which is also used for taking the failure light emission image can detect the light in a pixel unit, therefore, the second wiring pattern image can be obtained directly by the intensity of the incident light obtained in every pixel without such the arithmetical operation. Besides, even the second infrared light detector 42 can obtain time-divisionally the data of the intensity of the incident tight, thus it goes without saying that the laser scanning image by the arithmetical operation can be used as the second wiring pattern image.

The first wiring pattern image and the second wiring pattern image are both the laser scanning images which are based on the identical scanning of the laser beam 53a, thus each analysis region coincides completely with the other, and therefore, the alignment can be easily performed. Besides, the second wiring pattern image and the failure light emission image are both taken by the identical second infrared light detector 42, thus each analysis region (view) is identical with the other, and therefore, the alignment can be easily performed.

Accordingly, the alignment of the first wiring pattern image which is taken from the front side of the analyzed wafer 100 with the failure light emission image can be easily performed, according to the present preferred embodiment. That is, the specification of the position of the failure point which is taken from the back side upon the wiring pattern image which is obtained from the front side can be easily performed.

Besides, in FIG. 7, as the light source to obtain the wiring pattern image of the analyzed wafer 100, a formation is described that the laser optical system 53 is used which irradiates the laser beam 53a scanning on the analyzed wafer 100 from the back side, however, such as illustrated in FIG. 8, for example, it is also practical to use the laser optical system 54 which irradiates the laser beam 54a scanning from the front side. In this case, in addition to the effect described above, the laser beam 54a is irradiated from the front side of the analyzed wafer 100, thus an effect can be obtained that the first wiring pattern image which is taken from the front side can be obtained more clearly.

While the invention has been shown and described in detail, the foregoing description is in all aspects illustrative and not restrictive. It is therefore understood that numerous modifications and variations can be devised without departing from the scope of the invention.

What is claimed is:

1. A failure analysis method comprising the steps of:
(a) irradiating a first light which includes a component whose wave length is 1 μm or more upon a semiconductor chip which is an object for an analysis from a front side;
(b) taking both a first wiring pattern image which is a reflected image of said semiconductor chip by said first light and a second wiring pattern image which is a transmission image of said semiconductor chip by said first light; and
(c) taking a light emission image of said semiconductor chip by a failure point from a back side of said semiconductor chip,
wherein both said second wiring pattern image and said light emission image are taken by an identical image pickup device.

2. The failure analysis method according to claim 1, further comprising the steps of:
(d) irradiating a second light which includes a component whose wave length is 1 μm or more upon said semiconductor chip from a back side; and
(e) taking both a third wiring pattern image which is a reflected image of said semiconductor chip by said second light and a fourth wiring pattern image which is a transmission image of said semiconductor chip by said second light,
wherein said third wiring pattern image is taken by said identical image pickup device.

3. A failure analysis method comprising the steps of:
(a) irradiating a laser beam for scanning which includes a component whose wave length is 1 μm or more upon a semiconductor chip which is an object for an analysis, and taking a first wiring pattern image which is a transmission image of said semiconductor chip by said laser beam and a second wiring pattern image which is a reflected image of said semiconductor chip by said laser beam; and
(b) taking an image of a failure point of said semiconductor chip,
wherein said step (a) is performed by a first image pickup device which is placed on a front side of said semiconductor chip and a second image pickup device which is placed on a back side of said semiconductor chip,
said step (b) is performed by a third image pickup device which is placed on the back side of said semiconductor chip, and
in advance of said steps (a) and (b), an alignment of said second image pickup device with said third image pickup device is performed.

4. The failure analysis method according to claim 3,
wherein said step (b) includes the step of;
(c) taking a light emission image of said semiconductor chip by a failure point from the back side of said semiconductor chip.

5. The failure analysis method according to claim 3,
wherein said step (b) includes the step of:
irradiating said laser beam upon said semiconductor chip from the back side, and taking the image of said failure point using an OBIC method or an OBIRCH method.

6. A failure analysis method comprising the steps of:
(a) irradiating a laser beam for scanning which includes a component whose wave length is 1 μm or more upon a semiconductor chip which is an object for an analysis, and taking a first wiring pattern image which is a transmission image of said semiconductor chip by said laser beam and a second wiring pattern image which is a reflected image of said semiconductor chip by said laser beam; and
(b) taking an image of a failure point of said semiconductor chip,
wherein said step (a) is performed by a first image pickup device which is placed on a front side of said semiconductor chip and a second image pickup device which is placed on a back side of said semiconductor chip, and
said step (b) is performed by said second image pickup device.
